(19) United States
(12) Patent Application Publication
(10) Pub. No.: US 2026/0211330 A1
(43) Pub. Date: Jul. 23, 2026

(54) PATTERN TRANSFER BY DIRECTED SELF-ASSEMBLY (DSA) OF BLOCK COPOLYMERS (BCPS)

(71) Applicant: Applied Materials, Inc., Santa Clara, CA (US)

(72) Inventors: NASRIN KAZEM, Santa Clara, CA (US); SIVANANDHA KANAKASABAPATHY, Pleasanton, CA (US); RUDY WOJTECKI, East Garrison, CA (US)

(21) Appl. No.: 19/032,114

(22) Filed: Jan. 20, 2025

(51) Int. Cl. G03F 7/11; G03F 7/00; G03F 7/004; G03F 7/09; G03F 7/36

(52) U.S. Cl. CPC G03F 7/11; G03F 7/0043; G03F 7/094; G03F 7/36; G03F 7/70033

(57) ABSTRACT

Embodiments described herein relate to a method of patterning a resist layer with an exposed region and an unexposed region. In an embodiment, the method includes applying a block copolymer over the resist layer, where the block copolymer includes a polar region and a non-polar region, and where a chemical difference between the exposed region and the unexposed region allows for directed self-assembly of the block copolymer over the resist layer. In an embodiment, the method further includes selectively removing either the polar region or the non-polar region to form a patterned mask over the resist layer, and patterning the resist layer with an etching process using the patterned mask.

### BACKGROUND

### 1) Field

Embodiments relate to the field of semiconductor manufacturing and, in particular, patterning a resist layer using directed self-assembly (DSA) with block copolymers (BCPs).

### 2) Description of Related Art

Extreme ultraviolet (EUV) photoresists allow for the continued scaling to smaller features that are patterned on a semiconductor substrate. In an EUV lithography process, EUV radiation is selectively applied to regions of the photoresist layer in order to generate a solubility switch that enables the formation of a latent image within the photoresist layer. The latent image corresponds to the portions of the photoresist layer that have undergone the solubility switch as a result of a chemical reaction that is induced by the EUV exposure. After the latent image is produced within the photoresist layer, a developing process may be used in order to generate a pattern in the photoresist layer.

Typically, EUV compatible resists suffer from poor sensitivity. That is, a large dose is needed in order to provide the necessary solubility switch in order to provide adequate pattern formation (e.g., with suitable line edge roughness (LER), line width roughness (LWR), critical dimension uniformity (CDU), and/or the like). The larger dose increases the exposure time, which may be a bottleneck in the EUV lithography process.

### SUMMARY

Embodiments described herein relate to a method of patterning a resist layer with an exposed region and an unexposed region. In an embodiment, the method includes applying a block copolymer over the resist layer, where the block copolymer includes a polar region and a non-polar region, and where a chemical difference between the exposed region and the unexposed region allows for directed self-assembly of the block copolymer over the resist layer. In an embodiment, the method further includes selectively removing either the polar region or the non-polar region to form a patterned mask over the resist layer, and patterning the resist layer with an etching process using the patterned mask.

Embodiments described herein relate to a method for patterning an exposed resist layer that is over a substrate, where the exposed resist layer includes an exposed region and an unexposed region. In an embodiment, the method includes applying a block copolymer over the resist layer, and heating the block copolymer to initiate a directed self-assembly (DSA) process using the exposed region and the unexposed region as a template to segregate a polar region of the block copolymer from a non-polar region of the block copolymer. In an embodiment, the process further includes removing the polar region or the non-polar region to form a patterned mask over the resist layer, and etching the resist layer through the patterned mask.

Embodiments described herein relate to a method that includes exposing a resist layer with extreme ultraviolet (EUV) radiation to form an exposed region and an unexposed region, and applying a block copolymer over the resist layer. In an embodiment, the method further includes heating the block copolymer to allow for a directed self-assembly process to segregate a polar region of the block copolymer from a non-polar region of the block copolymer, where the exposed region and the unexposed region have chemical differences that provide a template to enable the directed self-assembly process. In an embodiment, the method further includes removing the polar region or the non-polar region to form a patterned mask over the resist layer, and etching the resist layer to form a patterned resist layer using the patterned mask.

### BRIEF DESCRIPTION OF THE DRAWINGS

FIG. 1A is a perspective view illustration of a device with a patterning layer and a resist layer over the patterning layer, in accordance with an embodiment.

FIG. 1B is a perspective view illustration of the device after the resist layer is exposed to form exposed regions and unexposed regions, in accordance with an embodiment.

FIG. 1C is a perspective view illustration of the device after a block copolymer is formed over the resist layer, in accordance with an embodiment.

FIG. 1D is a perspective view illustration of the device after one of the blocks is removed, in accordance with an embodiment.

FIG. 1E is a perspective view illustration of the device after the resist layer is patterned using the overlying block copolymer as a mask, in accordance with an embodiment.

FIG. 2A is a cross-sectional illustration of a device with an exposed resist layer and a segregated block copolymer over the resist layer, in accordance with an embodiment.

FIG. 2B is a cross-sectional illustration of the device after the block copolymer and the resist layer are patterned with an etching process, in accordance with an embodiment.

FIG. 2C is a cross-sectional illustration of the device after the pattern is transferred into the patterning layer under the resist layer, in accordance with an embodiment.

FIG. 2D is a cross-sectional illustration of the device after the resist layer and the block copolymer layer are removed is shown, in accordance with an embodiment.

FIG. 2E is a cross-sectional illustration of the device after the pattern is transferred into the underlying substrate, in accordance with an embodiment.

FIG. 3 is a flow diagram depicting a process for patterning a resist layer with an etching process that uses a block copolymer, in accordance with an embodiment.

FIG. 4 illustrates a block diagram of an exemplary computer system that may be used in conjunction with a processing tool, in accordance with an embodiment.

### DETAILED DESCRIPTION

Embodiments described herein include processes for patterning a resist layer using directed self-assembly (DSA) with block copolymers (BCPs). In the following description numerous specific details are set forth in order to provide a thorough understanding of embodiments. It will be apparent to one skilled in the art that embodiments may be practiced without these specific details. In other instances, well-known aspects are not described in detail in order to not unnecessarily obscure embodiments. Furthermore, it is to be understood that the various embodiments shown in the accompanying drawings are illustrative representations and are not necessarily drawn to scale.

Various embodiments or aspects of the disclosure are described herein. In some implementations, the different embodiments are practiced separately. However, embodiments are not limited to embodiments being practiced in isolation. For example, two or more different embodiments can be combined together in order to be practiced as a single device, process, structure, or the like. The entirety of various embodiments can be combined together in some instances. In other instances, portions of a first embodiment can be combined with portions of one or more different embodiments. For example, a portion of a first embodiment can be combined with a portion of a second embodiment, or a portion of a first embodiment can be combined with a portion of a second embodiment and a portion of a third embodiment.

The embodiments illustrated and discussed in relation to the figures included herein are provided for the purpose of explaining some of the basic principles of the disclosure. However, the scope of this disclosure covers all related, potential, and/or possible, embodiments, even those differing from the idealized and/or illustrative examples presented. This disclosure covers even those embodiments which incorporate and/or utilize modern, future, and/or as of the time of this writing unknown, components, devices, systems, etc., as replacements for the functionally equivalent, analogous, and/or similar, components, devices, systems, etc., used in the embodiments illustrated and/or discussed herein for the purpose of explanation, illustration, and example.

As noted above, resists used in extreme ultraviolet (EUV) lithography often suffer from low sensitivity to the EUV radiation. This requires large doses to be used in order to provide the desired resist pattern properties (e.g., line edge roughness (LER), line width roughness (LWR), critical dimension uniformity (CDU), etc.). Typically, a large dose-to-size (DtS) is used to achieve the desired patterning results. This can lead to long exposure times, which makes the EUV radiation exposure process a bottleneck in the lithography process.

Accordingly, embodiments disclosed herein include the use of a block copolymer layer over the resist layer. The block copolymer layer may be used to form a patterning mask. For example, the block copolymer layer may include a polar region and a non-polar region that allows for the formation of an alternating pattern. Chemical differences between the polar region and the non-polar region allow for one of the blocks to be preferentially etched, and the remaining block remains behind as a patterning mask. In some embodiments disclosed herein, the polar region may be referred to as a polar block of the block copolymer, and the non-polar region may be referred to as a non-polar block of the block copolymer. The patterning mask of the block copolymer can be used to etch the underlying resist layer. That is, the underlying resist layer is not developed in the traditional sense. The use of an etching process allows for the well-defined edges of the block copolymer to be transferred into the resist layer during the etching process. As such, high dosages are not needed in order to generate the desired pattern properties.

In an embodiment, the block copolymer is provided on the resist layer and allowed to segregate into alternating polar regions and non-polar regions with a directed self-assembly (DSA) process. The template to enable the DSA process is provided in the resist layer by selectively exposing portions of the resist layer to electromagnetic radiation (e.g., deep ultraviolet (DUV) radiation or extreme ultraviolet (EUV) radiation). The selective exposure of the resist layer produces a chemical difference between the exposed regions and the unexposed regions at the surface of the resist layer that enables the DSA process.

It is to be appreciated that such a template for the block copolymer is different than previous attempts to use block copolymers in lithography processes. Typically, the resist layer is exposed and developed to expose portions of an underlying layer. The exposed portions of the underlying layer are then treated (e.g., oxidized), and the resist layer is removed. Thereafter, the underlying layer includes treated regions and untreated regions that can be used as the template for the DSA process of the block copolymer. That is, in such a solution, the resist layer is developed to form the pattern. Accordingly, the resist layer still needs high dosages in order to provide the desired sidewall profile (e.g., LWR, LER, CDU, etc.) that can be transferred to the other layers with the lithography process. In contrast, embodiments disclosed herein set the sidewall profile (e.g., LWR, LER, CDU, etc.) through the block copolymer layer. This allows for the resist layer to be exposed with a dose that is sufficient to provide the chemical contrast used for the DSA process, while not needing a larger dose to provide the desired sidewall properties.

Accordingly, embodiments disclosed herein have lower demands on the resist material. For example, the chemical reactions, diffusion of species, etc. within the resist layer are not directly driving the sidewall properties. Instead of needing to engineer a resist material that is developable with good properties at low doses, embodiments allow for the patterning of the resist layer to be done through a mask (e.g., through a patterned block copolymer mask). As such, the simpler task of designing a DSA process that allows for good segregation between polar regions and non-polar regions of the block copolymer can be used in order to the define high quality patterning properties, such as excellent LER, LWR, CDU, and/or the like.

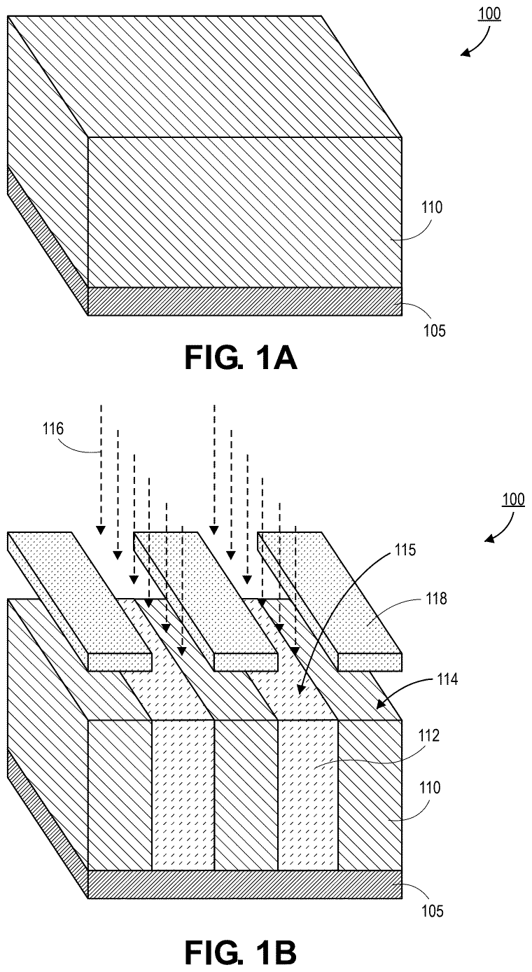

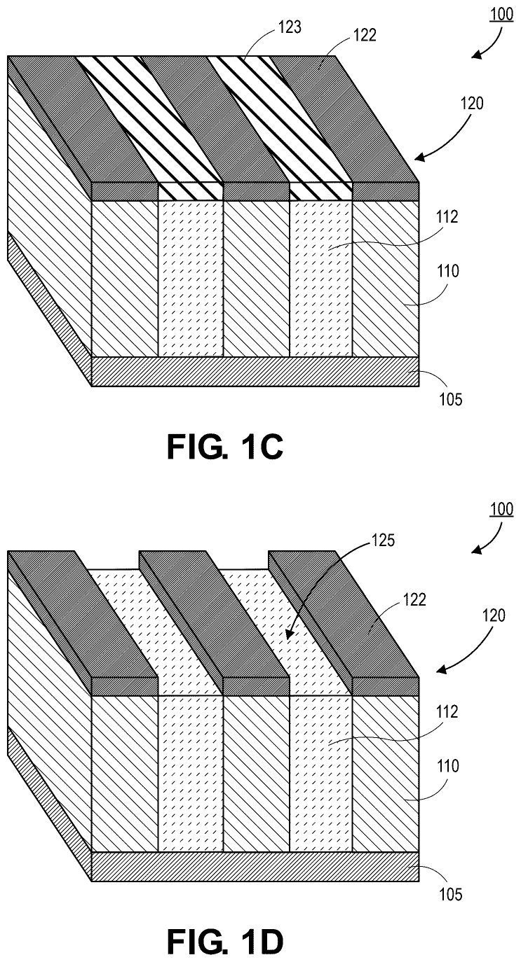

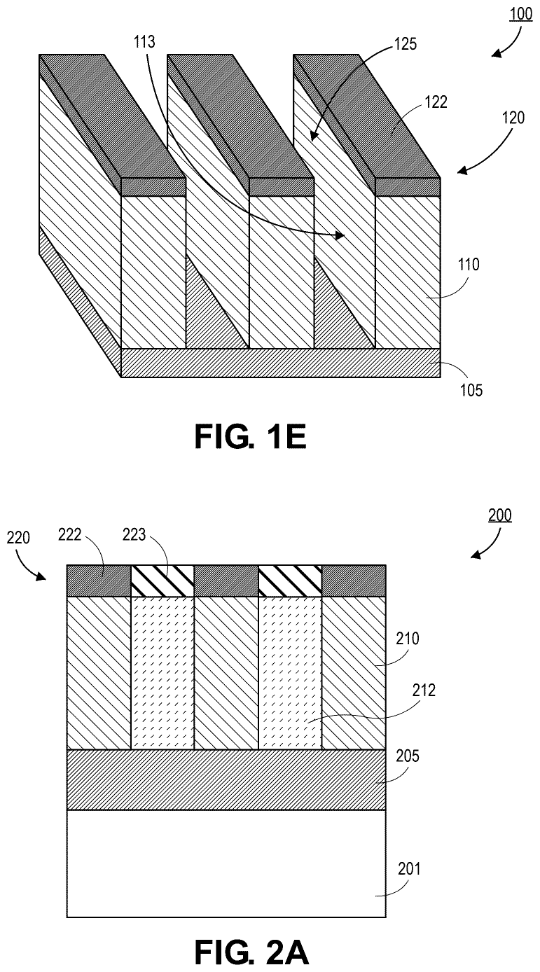

Referring now to FIGS. 1A-1E, a series of perspective view illustrations depicting a process for patterning a resist layer using a DSA process enabled by a block copolymer is shown, in accordance with an embodiment.

Referring now to FIG. 1A, a perspective view illustration of a portion of a device 100 is shown, in accordance with an embodiment. In an embodiment, the device 100 may include a patterning stack 105 and a resist layer 110 over the patterning stack 105. The resist layer 110 and the patterning stack 105 may be provided over a substrate (not shown). In an embodiment, a patterning stack 105 may include one or more layers suitable for transferring a pattern formed into the resist layer 110 into the underlying substrate. For example, the patterning stack 105 may comprise multiple layers, such as a silicon hardmask layer, a carbon hardmask layer, an antireflective coating, and/or the like. In some embodiments, the patterning stack 105 may comprise underlayer (not individually shown). In an embodiment, the underlayer may comprise a material that is sensitive to extreme ultraviolet (EUV) radiation or deep ultraviolet (DUV) radiation in order to generate species (e.g., elements, molecules, electrons, etc.) that can diffuse into the overlying resist layer 110 in order to participate in the solubility switch reaction. In an embodiment, the underlayer may be deposited with a dry deposition process (e.g., chemical vapor deposition (CVD), atomic layer deposition (ALD), or the like). Though, in other embodiments the underlayer may be omitted.

In an embodiment, the resist layer 110 may comprise a material that reacts when exposed to EUV and/or DUV radiation in order to generate a solubility switch. In a particular embodiment, the resist layer 110 may comprise a metal oxide resist (MOR) material. The resist material may also include an organometallic oxide material. In an embodiment a MOR material may comprise a photoresist material with one or more metals (e.g., tin, indium, hafnium, zinc, zirconium, or any combination thereof). The MOR material may also comprise an organotin-oxo photoresist material, an organoindium-oxo photoresist material, or the like. In other embodiments the resist layer 110 may comprise a chemically amplified resist (CAR).

Referring now to FIG. 1B, a perspective view illustration of the device 100 after the resist layer 110 is exposed to form exposed regions 112 is shown, in accordance with an embodiment. The unexposed regions of the resist layer 110 may sometimes be referred to as “unexposed regions 110” in some embodiments. In an embodiment, the resist layer 110 may be selectively exposed with EUV and/or DUV radiation 116. For example, the radiation 116 may be passed through a reticle or a mask 118, the radiation 116 may be applied with direct laser writing, or the like. In an embodiment, the exposed regions 112 may be a latent image that has a desired pattern within the resist layer 110. For example, the exposed regions 112 may have the pattern of lines to form traces in the underlying layers (e.g., the patterning stack 105 and an underlying substrate). In an embodiment, the exposed region 112 may refer to a region of the resist layer 110 that has undergone a chemical change (e.g., a cross-linking reaction, deprotection reaction, or the like) in order to alter the solubility with respect to a developing chemistry.

Of particular interest to embodiments disclosed herein, the selective exposure may result in a chemical contrast between a surface 115 of the exposed region 112 and a surface 114 of the unexposed region 110. For example, the chemical contrast may refer to a difference in the polarity of the surfaces 115 and 114. In one embodiment, one of the surfaces 115 or 114 may be polar, and the other of the surfaces 115 or 114 may be non-polar. As used herein, “polar and non-polar” may refer to a relative polarity difference between the surfaces 115 and 114. That is, the “non-polar surface” may have some amount of polarity, though the “non-polar surface” has a lower polarity than the “polar surface”.

In the case of a MOR resist material, the exposed region 112 may have a high concentration of OH groups at the surface 115 of the exposed region 112, and the unexposed region 110 may retain R-groups of the metal clusters at the surface 114 of the unexposed region 110. In the case of a CAR, the exposed region 112 may have a surface 115 with a high concentration of esters while the unexposed region 110 comprises an acid and/or hydroxyl side group dominated surface 114 and/or an oxygen rich surface 114. In some instances the exposed region 112 may be hydrophilic and the unexposed region 110 may be hydrophobic.

The generation of surfaces 114 and 115 that have alternating polarities serves as a template for a block copolymer layer to be applied and segregated through a DSA process. For example, the block copolymer may have a polar region and a non-polar region that self-assembles in response to the template provided by the surfaces 114 and 115.

Referring now to FIG. 1C, a perspective view illustration of the device after a block copolymer layer 120 is applied over the exposed regions 112 and the unexposed regions 110 is shown, in accordance with an embodiment. In an embodiment, the block copolymer layer 120 may be applied as a liquid and distributed over the device 100 with a spinning process (e.g., a spin coating process). As deposited, the block copolymer layer 120 may not have sufficient energy to distribute as an ordered layer. As such, some embodiments May include an annealing process in order to drive the DSA process to provide alternating blocks 123 and 122, as shown in FIG. 1C.

In an embodiment, the blocks 123 may be polar regions 123, and the blocks 122 may be non-polar regions 122. Accordingly, the polar regions 123 will segregate over the polar regions and the non-polar regions 122 will segregate over the non-polar regions. For example, polar regions 123 may be provided over the exposed regions 112, and the non-polar regions 122 may be provided over the non-polar regions. The block copolymer 120 may have a general structure such as:

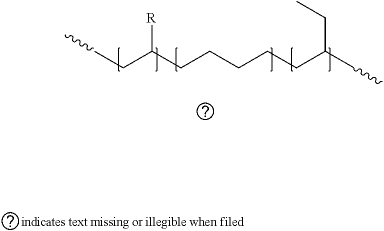

where R comprises an arene compound, such as one or more of:

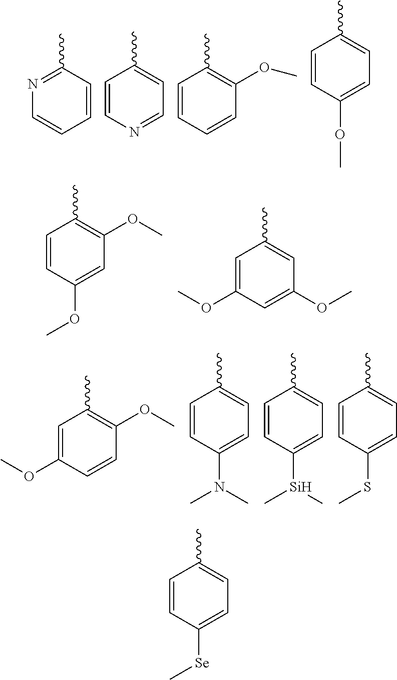

In a particular embodiment, the block copolymer 120 may comprise a hydroxystyrene, such as one or more of poly(hydroxystyrene-b-butadiene), poly(hydroxystyrene-b-hydrogenated butadiene), poly(vinylpyridine-b-butadiene), or poly(vinylpyridine-b-hydrogenated butadiene).

In an embodiment, the block copolymer 120 may be chosen to provide a desired tone for the patterning process. That is, embodiments allow for the generation of either a positive tone resist or a negative tone resist through the selection of the proper block copolymer 120. For example, a chemical structure that enhances etch resistance (e.g., a benzene ring or other arene structure) may be added to the polar region 123 or the non-polar region, depending on which tone is desired. For example, when the polar region 123 has an etch resistant structure, the non-polar region 122 will be preferentially etched to provide a negative tone resist, and when the non-polar region 122 has an etch resistant structure, the polar region 123 will be preferentially etched to provide a positive tone resist.

In an embodiment, a block copolymer 120 useful for a positive tone resist may comprise a non-polar region 122 that includes polystyrene and a polar region 123 that includes poly(methyl methacrylate) (PMMA). In an embodiment, a block copolymer 120 that is useful for a negative tone resist may comprise a non-polar region 122 that is a poly-hydrocarbon with a non-arene group (e.g., an alkyl group), and the polar region 123 may comprise a poly(hydroxystyrene), such as one or more of:

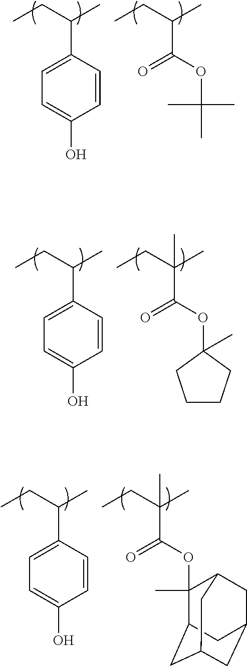

As can be appreciated, a highly efficient process for segregating the block copolymer 120 into the polar regions 123 and the non-polar regions 122 is beneficial for improving the speed of the process, as well as improving the patterning properties. Accordingly, some embodiments may select a block copolymer 120 with a high Flory-Huggins interaction parameter (χ). High χ block copolymers also allow for small feature sizes that enable improved scaling of the line-space dimensions used in advanced semiconductor manufacturing environments.

Referring now to FIG. 1D, a perspective view illustration of the portion of the device 100 after the block copolymer 120 is patterned in order to form a patterned mask over the resist layer 110 is shown, in accordance with an embodiment. In the illustrated embodiment, the polar region 123 is removed to form an opening 125 through the block copolymer 120. The polar region 123 may be removed with an etching process. However, as noted above, a negative tone resist may be manufactured by choosing a polar region 123 that has a higher etch resistance than the non-polar region 122. In such an embodiment, the unexposed regions of the resist layer 110 are exposed after the block copolymer patterning process.

Referring now to FIG. 1E, a perspective view illustration of the portion of the device 100 after a pattern of the block copolymer layer 120 is transferred into the resist layer 110 is shown, in accordance with an embodiment. In an embodiment, the resist layer 110 may be patterned with an etching process that etches the resist layer 110 through the opening 125 in the mask of the block copolymer layer 120. That is, patterning of the resist layer 110 is not entirely dependent on the chemical reactions induced by the EUV and/or DUV exposure. Instead, the opening 125 defines the pattern in the resist layer 110. Accordingly, the sidewall 113 may be straighter than a traditional resist development process. This provides better LER, LWR, and/or the like for the resist layer 110 without the need for high EUV and/or DUV dosages.

In an embodiment, the resist layer 110 may be etched with any suitable etching chemistry through a dry etching process. In the case of a MOR resist layer 110, an HBr based chemistry, or the like may be used. In the case of a CAR resist layer 110, a chemistry comprising one or more of O₂, CF₄, or any other suitable CAR etching chemistry may be used.

After the resist layer 110 is patterned, the pattern of the opening 125 may be transferred into the underlying patterning stack 105 with one or more etching processes. In some embodiments, the etching for the resist layer 110 and the patterning stack 105 may be implemented in a single chamber. This is beneficial compared to existing solutions that require a separate developing chamber in order to develop the resist layer using traditional processes.

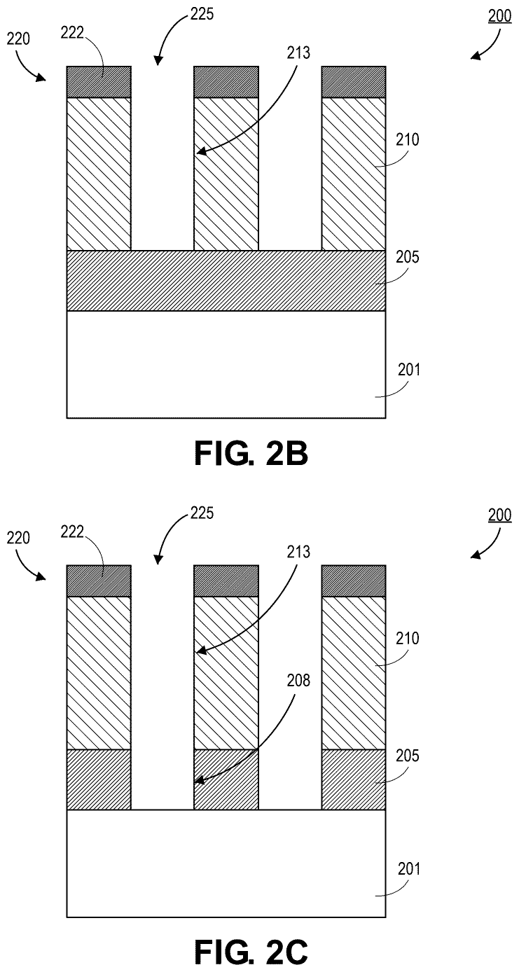

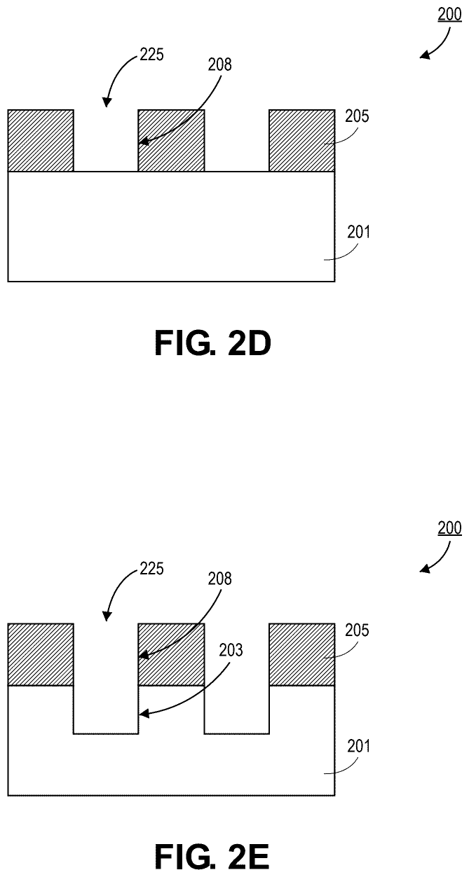

Referring now to FIGS. 2A-2E, a series of cross-sectional illustrations depicting a process for patterning the resist layer and transferring the pattern into an underlying patterning stack and substrate is shown, in accordance with an embodiment.

Referring now to FIG. 2A, a cross-sectional illustration of a portion of a device 200 is shown in accordance with an embodiment. In an embodiment, the device 200 is similar to the device 100 described in greater detail herein. For example, the device 200 may comprise a patterning stack 205 and a resist layer 210 over the patterning stack 205. The resist layer 210 may comprise an MOR material or a CAR material. In an embodiment, the patterning stack 205 may be provided over a substrate 201. In an embodiment, the substrate 201 may comprise a semiconductor material, such as a silicon wafer, an oxide layer, a nitride layer, a metallic layer, or the like.

In an embodiment, the resist layer 210 may have been exposed with EUV radiation and/or DUV radiation to form an exposed region 212. Thereafter, a block copolymer layer 220 is applied to the resist layer 210. The block copolymer layer 220 undergoes a DSA process in order to segregate a polar region 223 over the exposed regions 212 and a non-polar region 222 over the unexposed regions of the resist layer 210. In an embodiment, the DSA process and the materials chosen for the block copolymer 220 may be similar to those described above with respect to FIGS. 1A-1E.

Referring now to FIG. 2B, a cross-sectional illustration of the portion of the device 200 after an etching process is used to form an opening 225 through the block copolymer layer 220 and the resist layer 210 is shown, in accordance with an embodiment. In an embodiment, the block copolymer layer 220 is etched with an etching process that removes either the polar region 223 (as shown in FIG. 2B) or the non-polar region 222. An additional etching process may be used to etch through the resist layer 210 using the remaining portions of the block copolymer layer 220 as an etching mask. As can be appreciated, the sidewall 213 of the resist layer 210 within the openings 225 may be substantially aligned with the sidewall of the block copolymer layer 220 within the openings 225. That is, the patterning relies on the mechanical blocking of etchant species by the block copolymer layer 220 instead of the chemical reactions, diffusion, and/or the like within the resist layer 210 (as is the case with existing EUV resist developing processes). As such, the resist layer 210 may exhibit improved LER, LWR, CDU, etc. without the need to increase the EUV radiation dose.

In an embodiment, the resist layer 210 may be etched with a dry etching process that uses an etching chemistry suitable for the type of material used for the resist layer 210. In the case of a MOR resist layer 210, an HBr based chemistry, or the like may be used. In the case of a CAR resist layer 210, a chemistry comprising one or more of O₂, CF₄, or any other suitable CAR etching chemistry may be used.

Referring now to FIG. 2C, a cross-sectional illustration of the portion of the device 200 after the pattern of the openings 225 is transferred into the patterning stack 205 is shown, in accordance with an embodiment. In an embodiment, the patterning stack 205 may be patterned with any number of different etching chemistries (e.g., to etch through multiple different sub-layers (not individually shown) of the patterning stack 205). As shown in FIG. 2C, the sidewall 208 of the patterning stack 205 within the openings 225 may also be substantially linear with excellent LER, LWR, and CDU since the overlying resist layer 210 is used as the mask to pattern the patterning stack 205. In an embodiment, the etching process (or processes) used to pattern the patterning stack 205 may be implemented in the same chamber that is used to pattern the resist layer 210. As such, the throughput may be improved since a dedicated resist developing chamber may not be needed.

Referring now to FIG. 2D, a cross-sectional illustration of the portion of the device 200 after the block copolymer layer 220 and the resist layer 210 are removed is shown, in accordance with an embodiment. In an embodiment, the block copolymer layer 220 and the resist layer 210 may be removed with any suitable process. While shown as removing the block copolymer layer 220 and the resist layer 210, embodiments may maintain the resist layer 210 and the block copolymer layer 220 in other instances.

Referring now to FIG. 2E, a cross-sectional illustration of the portion of the device 200 after the pattern of the openings 225 is transferred into the underlying substrate 201 is shown, in accordance with an embodiment. The underlying substrate 201 may be patterned with any suitable etching process while using the patterning stack 205 as a mask. The sidewalls 203 of the substrate 201 within the openings 225 may also have good patterning parameters since the overlying patterning stack 205 had sidewalls 208 that were formed as a result of the block copolymer pattern.

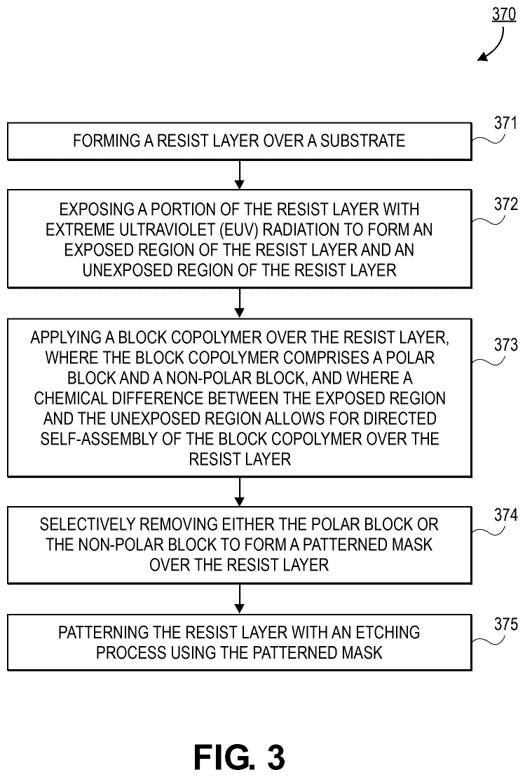

Referring now to FIG. 3, a flow diagram depicting a process 370 for patterning a resist layer through the use of a block copolymer and a DSA process is shown, in accordance with an embodiment. In an embodiment, the process 370 may include operations, materials, and/or the like similar to any of those described herein with respect to FIGS. 1A-1E and/or FIGS. 2A-2E.

In an embodiment, the process 370 may begin with operation 371, which comprises forming a resist layer over a substrate. In an embodiment, the resist layer may be a MOR material or a CAR material. The resist layer may be deposited over the substrate with a dry deposition process, a spin coating process, or any other suitable process. In an embodiment, a patterning stack may also be provided between the substrate and the resist layer.

In an embodiment, the process 370 may continue with operation 372, which comprises exposing a portion of the resist layer with EUV radiation (and/or DUV radiation) to form an exposed region of the resist layer and an unexposed region of the resist layer. In an embodiment, the exposure may be made through with the use of a mask or a retinal. Direct laser writing may also be used for the exposure process. In an embodiment, the exposure may be a relatively low dose exposure since the exposure just needs to generate a chemical contrast between the surfaces of the exposed region and the unexposed region.

In an embodiment, the process 370 may continue with operation 373, which comprises applying a block copolymer over the resist layer. In an embodiment, the block copolymer comprises a polar region and a non-polar region. The block copolymer may be applied with a spin coating process or the like. In an embodiment, a chemical difference (e.g., a polar surface versus a non-polar surface) between the exposed region and the unexposed region allows for a DSA process of the block copolymer over the resist layer. For example, the DSA process may include a heating or an annealing process that allows the polar regions to align with the polar exposed regions and the non-polar regions to align with the non-polar unexposed regions. That is, the annealing may initiate the DSA process.

In an embodiment, the block copolymer may be similar to any of the block copolymers described in greater detail herein. In some embodiments, the polar regions are etch resistant to provide a negative tone resist, and in other embodiments the non-polar regions are etch resistant to provide a positive tone resist.

In an embodiment, the process 370 may continue with operation 374, which comprises selectively removing either the polar region or the non-polar region to form a patterned mask over the resist layer. In an embodiment, the removal of one of the polar region or the non-polar region may be done with an etching process. In an embodiment, the patterned mask may have an opening that forms a line/space pattern.

In an embodiment, the process 370 may continue with operation 375, which comprises patterning the resist layer with an etching process using the patterned mask. The etching process may be a dry etching process. Any of the etching chemistries for MOR materials or CAR materials described herein may be used to etch the resist layer. The use of a mask during the etching process allows for improved LER, LWR, and/or CDU compared to traditional resist development processes which rely on the diffusion and chemical reactions through the thickness of the resist layer. Accordingly, improved patterning performance is obtained without increasing the dose of the EUV radiation and/or DUV radiation during exposure.

After the resist layer is patterned, the pattern defined by the opening can be transferred into the layers below the resist layer, such as a patterning stack and/or a substrate. Further, the etching process to pattern the resist layer may be implemented in the same chamber as the etching process (or processes) used to etch the underlying layers. As such, fewer chambers and chamber transfers are needed to execute the process. As such, the throughput and cost of the process can be reduced.

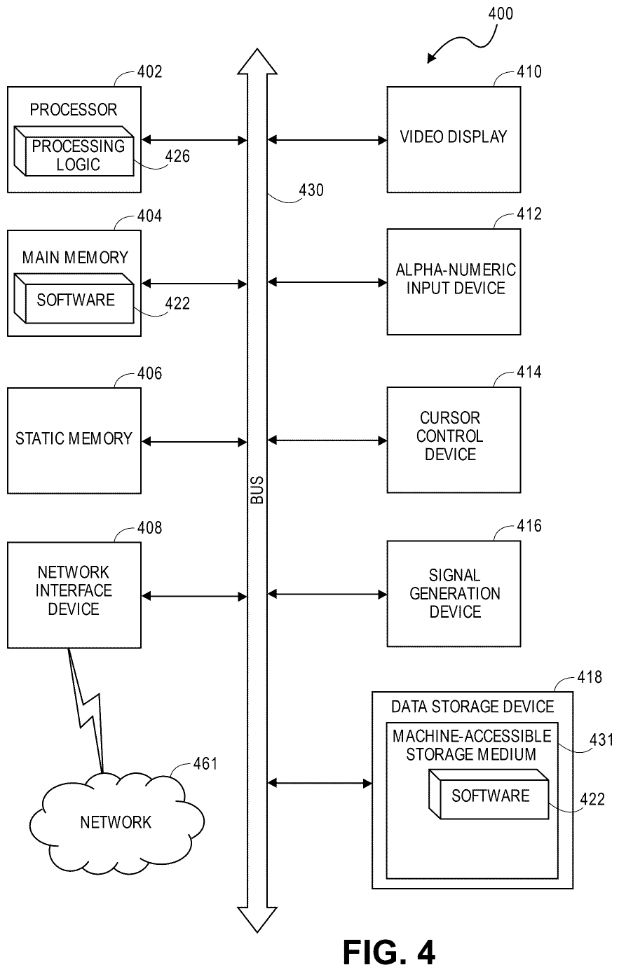

Referring now to FIG. 4, a block diagram of an exemplary computer system 400 of a processing tool is illustrated in accordance with an embodiment. In an embodiment, computer system 400 is coupled to and controls processing in the processing tool. Computer system 400 may be connected (e.g., networked) to other machines in a Local Area Network (LAN), an intranet, an extranet, or the Internet. Computer system 400 may operate in the capacity of a server or a client machine in a client-server network environment, or as a peer machine in a peer-to-peer (or distributed) network environment. Computer system 400 may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated for computer system 400, the term “machine” shall also be taken to include any collection of machines (e.g., computers) that individually or jointly execute a set (or multiple sets) of instructions to perform any one or more of the methodologies described herein.

Computer system 400 may include a computer program product, or software 422, having a non-transitory machine-readable medium having stored thereon instructions, which may be used to program computer system 400 (or other electronic devices) to perform a process according to embodiments. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

In an embodiment, computer system 400 includes a system processor 402, a main memory 404 (e.g., read-only memory (ROM), flash memory, dynamic random access memory (DRAM) such as synchronous DRAM (SDRAM) or Rambus DRAM (RDRAM), etc.), a static memory 406 (e.g., flash memory, static random access memory (SRAM), etc.), and a secondary memory 418 (e.g., a data storage device), which communicate with each other via a bus 430.

System processor 402 represents one or more general-purpose processing devices such as a microsystem processor, central processing unit, or the like. More particularly, the system processor may be a complex instruction set computing (CISC) microsystem processor, reduced instruction set computing (RISC) microsystem processor, very long instruction word (VLIW) microsystem processor, a system processor implementing other instruction sets, or system processors implementing a combination of instruction sets. System processor 402 may also be one or more special-purpose processing devices such as an application specific integrated circuit (ASIC), a field programmable gate array (FPGA), a digital signal system processor (DSP), network system processor, or the like. System processor 402 is configured to execute the processing logic 426 for performing the operations described herein.

The computer system 400 may further include a system network interface device 408 for communicating with other devices or machines. The computer system 400 may also include a video display unit 410 (e.g., a liquid crystal display (LCD), a light emitting diode display (LED), or a cathode ray tube (CRT)), an alphanumeric input device 412 (e.g., a keyboard), a cursor control device 414 (e.g., a mouse), and a signal generation device 416 (e.g., a speaker).

The secondary memory 418 may include a machine-accessible storage medium 431 (or more specifically a computer-readable storage medium) on which is stored one or more sets of instructions (e.g., software 422) embodying any one or more of the methodologies or functions described herein. The software 422 may also reside, completely or at least partially, within the main memory 404 and/or within the system processor 402 during execution thereof by the computer system 400, the main memory 404 and the system processor 402 also constituting machine-readable storage media. The software 422 may further be transmitted or received over a network 461 via the system network interface device 408. In an embodiment, the network interface device 408 may operate using RF coupling, optical coupling, acoustic coupling, or inductive coupling.

While the machine-accessible storage medium 431 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies. The term “machine-readable storage medium” shall accordingly be taken to include, but not be limited to, solid-state memories, and optical and magnetic media.

In the foregoing specification, specific exemplary embodiments have been described. It will be evident that various modifications may be made thereto without departing from the scope of the following claims. The specification and drawings are, accordingly, to be regarded in an illustrative sense rather than a restrictive sense.

What is claimed is:

1. A method of patterning a resist layer with an exposed region and an unexposed region, the method comprising:
applying a block copolymer over the resist layer, wherein the block copolymer comprises a polar region and a non-polar region, and wherein a chemical difference between the exposed region and the unexposed region allows for directed self-assembly of the block copolymer over the resist layer;
selectively removing either the polar region or the non-polar region to form a patterned mask over the resist layer; and
patterning the resist layer with an etching process using the patterned mask.

2. The method of claim 1, wherein the resist layer is a chemically amplified resist (CAR).

3. The method of claim 2, wherein the chemical difference comprises an ester rich surface on the exposed region and a relatively hydrophobic surface on the unexposed region with respect to the exposed region.

4. The method of claim 1, wherein the resist layer is a metal oxide resist (MOR).

5. The method of claim 4, wherein the chemical difference comprises a hydroxy and/or oxygen rich surface on the exposed region and a relatively hydrophobic surface on the unexposed region with respect to the exposed region.

6. The method of claim 1, wherein the non-polar region comprises a non-polar arene.

7. The method of claim 1, wherein the polar region comprises a hydroxystyrene.

8. The method of claim 1, wherein the polar region is removed to form the patterned mask over the resist layer.

9. The method of claim 1, wherein the non-polar region is removed to form the patterned mask over the resist layer.

10. The method of claim 1, wherein the block copolymer comprises poly(hydroxystyrene-b-butadiene), poly(hydroxystyrene-b-hydrogenated butadiene), poly(vinylpyridine-b-butadiene), or poly(vinylpyridine-b-hydrogenated butadiene).

11. A method for patterning an exposed resist layer that is over a substrate, wherein the exposed resist layer comprises an exposed region and an unexposed region, the method comprising:
applying a block copolymer over the resist layer;
heating the block copolymer to initiate a directed self-assembly (DSA) process using the exposed region and the unexposed region as a template to segregate a polar region of the block copolymer from a non-polar region of the block copolymer;
removing the polar region or the non-polar region to form a patterned mask over the resist layer; and
etching the resist layer through the patterned mask.

12. The method of claim 11, wherein the resist layer is a chemically amplified resist (CAR).

13. The method of claim 11, wherein the resist layer is a metal oxide resist (MOR).

14. The method of claim 11, wherein a first polarity of the exposed region is greater than a second polarity of the unexposed region.

15. The method of claim 14, wherein the second polarity is substantially non-polar.

16. The method of claim 11, wherein the block copolymer comprises poly(hydroxystyrene-b-butadiene), poly(hydroxystyrene-b-hydrogenated butadiene), poly(vinylpyridine-b-butadiene), or poly(vinylpyridine-b-hydrogenated butadiene).

17. The method of claim 11, further comprising:
using the resist layer as a mask to etch a layer below the resist layer after the resist layer is patterned with the etching process.

18. A method, comprising:
exposing a resist layer with extreme ultraviolet (EUV) radiation to form an exposed region and an unexposed region;
applying a block copolymer over the resist layer;
heating the block copolymer to allow for a directed self-assembly process to segregate a polar region of the block copolymer from a non-polar region of the block copolymer, wherein the exposed region and the unexposed region have chemical differences that provide a template to enable the directed self-assembly process;
removing the polar region or the non-polar region to form a patterned mask over the resist layer; and
etching the resist layer to form a patterned resist layer using the patterned mask.

19. The method of claim 18, wherein the resist layer is a chemically amplified resist (CAR) or a metal oxide resist (MOR).

20. The method of claim 18, wherein the block copolymer comprises poly(hydroxystyrene-b-butadiene), poly(hydroxystyrene-b-hydrogenated butadiene), poly(vinylpyridine-b-butadiene), or poly(vinylpyridine-b-hydrogenated butadiene).
